(19) United States
(12) Patent Application Publication
(10) Pub. No.: US 2025/0221143 A1
(43) Pub. Date: Jul. 3, 2025

(54) SEMICONDUCTOR DEVICE AND RADIATION DETECTOR

(71) Applicant: Japan Display Inc., Tokyo (JP)

(72) Inventors: Marina MOCHIZUKI, Tokyo (JP); Masashi TSUBUKU, Tokyo (JP); Hajime WATAKABE, Tokyo (JP); Toshinari SASAKI, Tokyo (JP); Takaya TAMARU, Tokyo (JP); Masahiro WATABE, Tokyo (JP)

(73) Assignee: Japan Display Inc., Tokyo (JP)

(21) Appl. No.: 18/969,455

(22) Filed: Dec. 5, 2024

(30) Foreign Application Priority Data
Dec. 28, 2023 (JP) 2023-223144

(51) Int. Cl. H10K 39/36; G01T 1/20

(52) U.S. Cl. CPC H10K 39/36; G01T 1/2018

(57) ABSTRACT

A semiconductor device according to an embodiment of the present invention includes: a semiconductor layer arranged above an insulating surface; a first gate electrode arranged above the semiconductor layer and facing the semiconductor layer; a first insulating layer arranged between the semiconductor layer and the first gate electrode and containing a silicon oxide covering a pattern end of the semiconductor layer; a second insulating layer arranged above the first insulating layer between the semiconductor layer and the first gate electrode, the second insulating layer having a common planar shape with the first gate electrode and containing a first metal oxide; and a third insulating layer arranged above the second insulating layer between the semiconductor layer and the first gate electrode, the third insulating layer having a common planar shape with the first gate electrode and containing a silicon nitride.

### CROSS-REFERENCE TO RELATED APPLICATION

This application claims the benefit of priority to Japanese Patent Application No. 2023-223144, filed on Dec. 28, 2023, the entire contents of which are incorporated herein by reference.

### FIELD

An embodiment of the present invention relates to a semiconductor device and a radiation detector. In particular, an embodiment of the present invention relates to a radiation detector including a semiconductor device in which an oxide semiconductor is used as a channel.

### BACKGROUND

In recent years, instead of amorphous silicon, low-temperature polysilicon, and single crystal silicon, development of a semiconductor device in which an oxide semiconductor is used as a channel has been advanced (for example, Japanese Laid-Open Patent Publication No. 2021-141338). The semiconductor device in which the oxide semiconductor is used as the channel can be formed by a simple structure and a low-temperature process similar to a semiconductor device in which amorphous silicon is used as a channel. It is known that the semiconductor device in which the oxide semiconductor is used as the channel has higher mobility than the semiconductor device in which the amorphous silicon is used as the channel.

In order for the semiconductor device in which the oxide semiconductor is used as the channel to operate stably, it is important to reduce oxygen vacancies formed in an oxide semiconductor layer by supplying oxygen to the oxide semiconductor layer in a manufacturing process of the semiconductor device. For example, a technique of forming an insulating layer covering the oxide semiconductor layer under a condition that the insulating layer contains more oxygen is disclosed as a method of supplying oxygen to the oxide semiconductor layer.

### SUMMARY

A semiconductor device according to an embodiment of the present invention includes: a semiconductor layer arranged above an insulating surface; a first gate electrode arranged above the semiconductor layer and facing the semiconductor layer; a first insulating layer arranged between the semiconductor layer and the first gate electrode and containing a silicon oxide covering a pattern end of the semiconductor layer; a second insulating layer arranged above the first insulating layer between the semiconductor layer and the first gate electrode, the second insulating layer having a common planar shape with the first gate electrode and containing a first metal oxide; and a third insulating layer arranged above the second insulating layer between the semiconductor layer and the first gate electrode, the third insulating layer having a common planar shape with the first gate electrode and containing a silicon nitride.

### BRIEF DESCRIPTION OF DRAWINGS

FIG. 1 is a cross-sectional view showing an outline of a radiation detector according to an embodiment of the present invention.

FIG. 2 is a circuit diagram showing an outline of a radiation detector according to an embodiment of the present invention.

FIG. 3 is a cross-sectional view of a semiconductor device according to an embodiment of the present invention.

FIG. 4 is a cross-sectional view of a semiconductor device according to a comparative example and its electrical characteristics.

FIG. 5 is a cross-sectional view of a semiconductor device according to a comparative example and its electrical characteristics.

FIG. 6 is a cross-sectional view of a semiconductor device according to a comparative example and its electrical characteristics.

FIG. 7 is a cross-sectional view of a semiconductor device according to a comparative example and its electrical characteristics.

FIG. 8 is a cross-sectional view of a semiconductor device according to a comparative example and its electrical characteristics.

FIG. 9 is a cross-sectional view of a semiconductor device according to an embodiment of the present invention and its electrical characteristics.

FIG. 10 is a diagram showing the results of a reliability test against radiation of a semiconductor device according to an embodiment of the present invention.

FIG. 11 is a cross-sectional view showing a method for manufacturing a semiconductor device according to an embodiment of the present invention.

FIG. 12 is a cross-sectional view showing a method for manufacturing a semiconductor device according to an embodiment of the present invention.

FIG. 13 is a cross-sectional view showing a method for manufacturing a semiconductor device according to an embodiment of the present invention.

FIG. 14 is a cross-sectional view showing a method for manufacturing a semiconductor device according to an embodiment of the present invention.

FIG. 15 is a cross-sectional view showing a method for manufacturing a semiconductor device according to an embodiment of the present invention.

FIG. 16 is a cross-sectional view showing a method for manufacturing a semiconductor device according to an embodiment of the present invention.

FIG. 17 is a cross-sectional view showing a method for manufacturing a semiconductor device according to an embodiment of the present invention.

FIG. 18 is a cross-sectional view showing a method for manufacturing a semiconductor device according to an embodiment of the present invention.

### DESCRIPTION OF EMBODIMENTS

Hereinafter, embodiments of the present invention will be described with reference to the drawings. The following disclosure is merely an example. A configuration that can be easily conceived by a person skilled in the art by appropriately changing the configuration of the embodiment while keeping the gist of the invention is naturally included in the scope of the present invention. For clarity of explanation, the drawings may be schematically represented with respect to widths, thicknesses, shapes, and the like of respective portions as compared with actual embodiments. However, the shown shapes are merely examples, and do not limit the interpretation of the present invention. In the present specification and the drawings, the same reference signs are given to the same components as those described above with respect to the drawings already described and detailed description thereof may be omitted as appropriate.

In each embodiment of the present invention, a direction from a substrate toward an oxide semiconductor layer is referred to as “upper” or “above”. Conversely, a direction from the oxide semiconductor layer toward the substrate is referred to as “lower” or “below”. As described above, for convenience of explanation, although the term “above” or “below” will be used for explanation, for example, the vertical relationship between the substrate and the oxide semiconductor layer may be different from that shown in the diagrams. In the following description, for example, the expression “oxide semiconductor layer on the substrate” merely describes the vertical relationship between the substrate and the oxide semiconductor layer as described above, and other members may be arranged between the substrate and the oxide semiconductor layer. Above or below means a stacking order in a structure in which a plurality of layers is stacked, and in the case where a first member is expressed as a first member above the transistor, the transistor and the first member may have a positional relationship in which the transistor and the first member do not overlap in a plan view. On the other hand, the expression “first member vertically above the transistor” means a positional relationship in which the transistor and the first member overlap in a plan view.

As used herein, the phrases “α includes A, B, or C,” “α includes any of A, B, or C,” “α includes one selected from a group consisting of A, B, and C,” and the like do not exclude the case where a includes a plurality of combinations of A to C unless otherwise indicated. Furthermore, these expressions do not exclude the case where a includes other elements.

In addition, the following embodiments can be combined with each other as long as there is no technical contradiction.

An insulating layer formed under a condition of containing more oxygen contains many defects. Due to this effect, a characteristic variation of the semiconductor device in a reliability test occurs. The characteristic variation in the reliability test is considered to be caused by the trapping of holes in the defects in the insulating layer. In the case where a semiconductor device in which a hole trap is formed is used in a detector for radiation, a characteristic variation of the semiconductor device occurs due to trapping of a hole generated by irradiation of the radiation. It is required to suppress such characteristic variation.

An object of an embodiment of the present invention is to realize a highly reliable semiconductor device for a radiation detector.

### [1. Configuration of Radiation Detector 10]

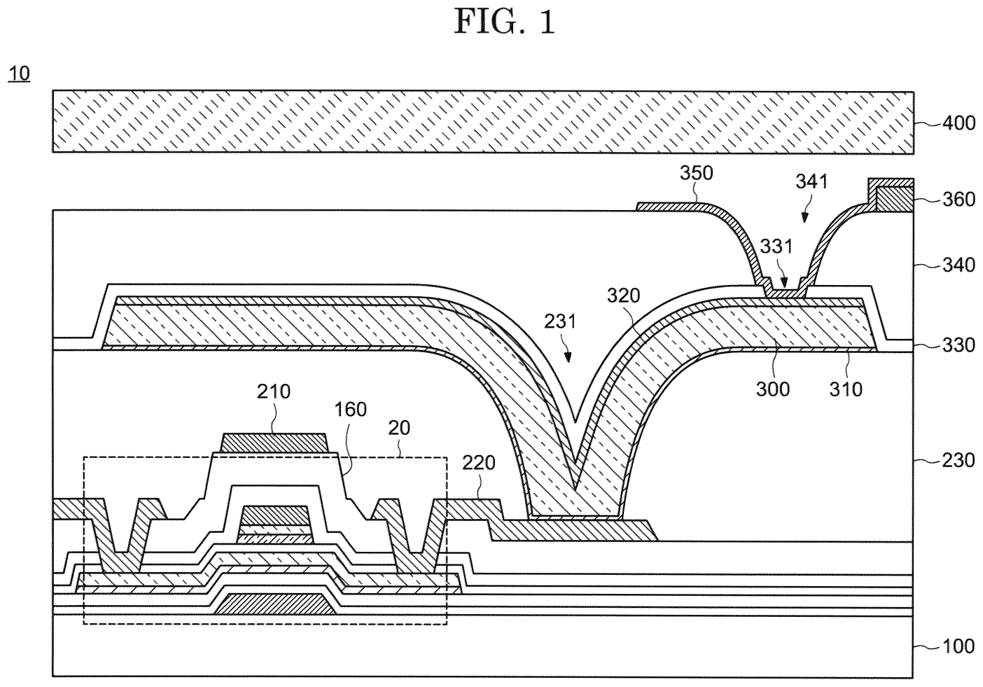

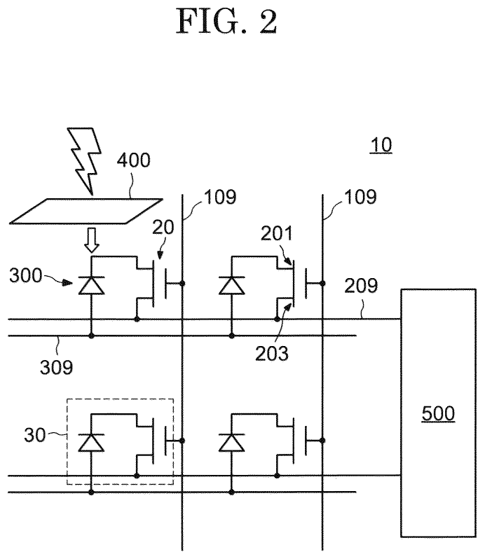

A configuration of a radiation detector 10 according to an embodiment of the present invention will be described with reference to FIG. 1 and FIG. 2. FIG. 1 is a cross-sectional view showing an outline of a radiation detector according to an embodiment of the present invention. FIG. 2 is a circuit diagram showing an outline of a radiation detector according to an embodiment of the present invention.

As shown in FIG. 1, the radiation detector 10 is arranged on a substrate 100. The radiation detector 10 includes a semiconductor device 20, a photoelectric conversion layer 300, and a wavelength conversion layer 400. The radiation detector 10 includes, in addition to the members described above, a light-shielding layer 210, a connection wiring 220, an insulating layer 230, a lower electrode 310, an upper electrode 320, insulating layers 330 and 340, and wirings 350 and 360. A detailed structure of the semiconductor device 20 will be described later.

The top layer of the semiconductor device 20 is an insulating layer 160. The light-shielding layer 210 is arranged on the insulating layer 160. The light-shielding layer 210 is arranged in a region overlapping an oxide semiconductor layer 140 constituting a channel of the semiconductor device 20 in a plan view. In a top view, the light-shielding layer 210 is arranged so as to cover at least the oxide semiconductor layer 140 in a channel region. The connection wiring 220 is arranged on the insulating layer 160 and is connected to the semiconductor device 20. Although details will be described later, the connection wiring 220 is connected to a source electrode 201 of the semiconductor device 20.

The insulating layer 230 is arranged on the insulating layer 160, the light-shielding layer 210, and the connection wiring 220. The insulating layer 230 covers a pattern end of the light-shielding layer 210 and a pattern end of the connection wiring 220. The insulating layer 230 releases a step formed by the semiconductor device 20, the light-shielding layer 210, and the connection wiring 220. The insulating layer 230 may be referred to as a planarization layer. An organic insulating layer is used as the insulating layer 230. An opening 231 is arranged in the insulating layer 230. The opening 231 reaches the connection wiring 220.

The lower electrode 310 is arranged on the insulating layer 230 and inside the opening 231. The lower electrode 310 is in contact with the connection wiring 220 at the bottom of the opening 231. The photoelectric conversion layer 300 and the upper electrode 320 are arranged on the lower electrode 310. That is, the photoelectric conversion layer 300 is connected to the semiconductor device 20 via the lower electrode 310 and the connection wiring 220. The photoelectric conversion layer 300 includes an N-type semiconductor layer, a P-type semiconductor layer, and an intrinsic semiconductor layer. The intrinsic semiconductor layer is arranged between the N-type semiconductor layer and the P-type semiconductor layer. One of the N-type semiconductor layer and the P-type semiconductor layer is in contact with the lower electrode 310, and the other is in contact with the upper electrode 320.

The photoelectric conversion layer 300 has a function of converting light energy into electrical energy. When the light energy is absorbed by the intrinsic semiconductor layer of the photoelectric conversion layer 300, the semiconductor is photoexcited to generate a pair of electrons and holes. The generated electrons and holes flow through the N-type semiconductor layer and the P-type semiconductor layer to the lower electrode 310 and the upper electrode 320. The intensity of the light irradiated to the photoelectric conversion layer 300 can be detected by detecting a current generated by the electrons and the holes generated by the photoexcitation.

The insulating layer 330 is arranged on the upper electrode 320. An opening 331 is arranged on the insulating layer 330. The opening 331 reaches the upper electrode 320. The insulating layer 340 is arranged on the insulating layer 330. An opening 341 is arranged on the insulating layer 340. In a plan view, the opening 341 is larger than the opening 331. The opening 341 reaches portions of the upper electrode 320 and the insulating layer 330. An inorganic insulating layer is used as the insulating layer 330. An organic insulating layer is used as the insulating layer 340. The insulating layer 330 has a shape reflecting steps formed by the lower electrode 310, the photoelectric conversion layer 300, and the upper electrode 320. On the other hand, the insulating layer 340 releases the steps. That is, the insulating layer 340 is a planarization layer.

The wiring 360 is arranged on the insulating layer 340 and in a region not overlapping the photoelectric conversion layer 300 in a plan view. The wiring 350 is arranged on the insulating layer 340, on the wiring 360, and inside the opening 341. The wiring 350 is in contact with the upper electrode 320 at the bottom of the opening 341.

Although details will be described later, in order for visible light emitted from the wavelength conversion layer 400 to efficiently reach the photoelectric conversion layer 300, a transparent conductive layer is used as the upper electrode 320 and the wiring 350. On the other hand, the wiring 360 is an opaque metal layer. The electrical resistance of the metal layer used as the wiring 360 is lower than the electrical resistance of the transparent conductive layer used as the wiring 350. However, a transparent conductive layer may be used as the wiring 360.

The wavelength conversion layer 400 is arranged above the wiring 350 so as to face the photoelectric conversion layer 300. The wavelength conversion layer 400 may be bonded to the wiring 350 and the insulating layer 340 by an adhesive layer, or a positional relationship between the wiring 350 and the insulating layer 340 may be fixed by a different fixing member. The wavelength conversion layer 400 has a function of converting radiation into visible light. For example, the wavelength conversion layer 400 includes a phosphor that absorbs X-rays, α-rays, or γ-rays and emits visible light. The wavelength conversion layer 400 may be referred to as a scintillator.

When radiation enters the wavelength conversion layer 400 from above, the radiation is converted into visible light by the wavelength conversion layer 400. When the converted visible light enters the photoelectric conversion layer 300, light energy is converted into electric energy, and the converted electric energy is detected as a current. Since there is a correlation between the intensity of the radiation incident on the wavelength conversion layer 400 and the detected current, the intensity of the radiation can be evaluated from a magnitude of the current.

As shown in FIG. 2, pixels 30 are arranged in a matrix in the radiation detector 10. The pixel 30 includes the semiconductor device 20 and the photoelectric conversion layer 300. A gate electrode of the semiconductor device 20 is connected to a gate control line 109. The source electrode 201 of the semiconductor device 20 is connected to a cathode of the photoelectric conversion layer 300. An anode of the photoelectric conversion layer 300 is connected to a wiring 309. A drain electrode 203 of the semiconductor device 20 is connected to a wiring 209. The wiring 209 is connected to a charge amplifier circuit 500.

As described above, the radiation incident on the wavelength conversion layer 400 is converted into visible light, and the visible light is converted into electric energy by the photoelectric conversion layer 300. In this case, by supplying a bias voltage to the wiring 309 connected to the pixel 30 for detecting radiation and supplying a signal for controlling the semiconductor device 20 to be in an ON state to the gate control line 109 connected to the pixel 30, the electric energy is detected as a current flowing through the semiconductor device 20. The current flowing through the semiconductor device 20 is supplied to the charge amplifier circuit 500 via the wiring 209. Then, the charge amplifier circuit 500 converts a charge signal into a voltage signal, and outputs the voltage signal to the outside. It is possible to evaluate the intensity of the radiation irradiated to the pixel 30 by the above operation.

As shown in FIG. 1, ideally, all of the radiation incident from above is absorbed by the wavelength conversion layer 400, but in practice, part of the radiation is transmitted through the wavelength conversion layer 400. Furthermore, ideally, the radiation transmitted through the wavelength conversion layer 400 is blocked by the light-shielding layer 210, but in practice, the radiation passes around the light-shielding layer 210 due to reflection by another member or the like, and reaches the oxide semiconductor layer 140. When radiation enters the oxide semiconductor layer 140, a pair of electrons and holes are generated in the oxide semiconductor layer 140. In the case where a hole trap is formed in the oxide insulating layer adjacent to the oxide semiconductor layer 140, the generated hole is trapped in the oxide insulating layer. This may cause a problem in that the electrical characteristics of the semiconductor device 20 shift in a negative direction.

### [2. Configuration of Semiconductor Device 20]

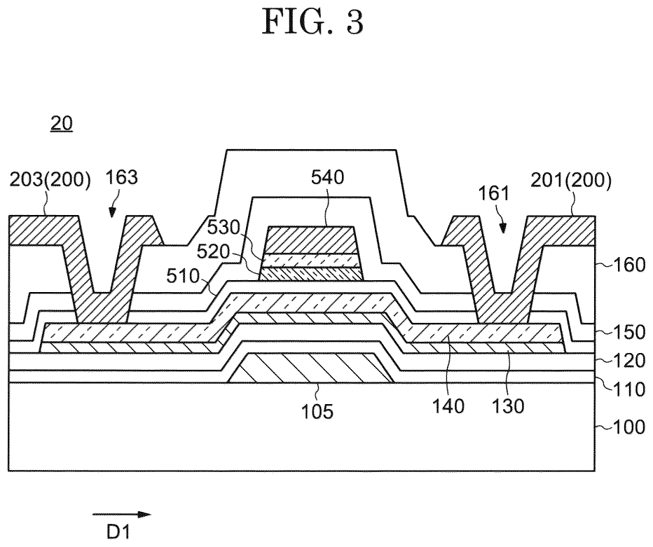

A configuration of the semiconductor device 20 included in the radiation detector 10 according to an embodiment of the present invention will be described with reference to FIG. 3. FIG. 3 is a cross-sectional view of a semiconductor device according to an embodiment of the present invention.

As shown in FIG. 3, the semiconductor device 20 is arranged on the substrate 100 having an insulating surface. The semiconductor device 20 includes a gate electrode 105, gate insulating layers 110 and 120, an insulating layer 130, the oxide semiconductor layer 140, gate insulating layers 510, 520, and 530, a gate electrode 540, the insulating layers 150 and 160, the source electrode 201, and the drain electrode 203. The semiconductor device 20 is a transistor in which the oxide semiconductor layer 140 is used for a channel. Depending on a polarity of the transistor, a circuit configuration, or a potential of each node, the source electrode and the drain electrode of the transistor may be replaced with each other. In the case where the source electrode 201 and the drain electrode 203 are not particularly distinguished, they may be collectively referred to as a source/drain electrode 200. The semiconductor device 20 may be a transistor in which a semiconductor other than the oxide semiconductor is used for the channel.

In the present embodiment, a dual-gate transistor in which the gate electrode 105 is arranged below the oxide semiconductor layer 140 and the gate electrode 540 is arranged above the oxide semiconductor layer 140 will be described as the semiconductor device 20. However, the semiconductor device 20 may be a bottom-gate transistor in which only the gate electrode 105 is arranged, or may be a top-gate transistor in which only the gate electrode 540 is arranged.

The gate electrode 105 is arranged on the substrate 100. The gate electrode 105 faces the oxide semiconductor layer 140. The gate insulating layers 110 and 120 are arranged between the gate electrode 105 and the oxide semiconductor layer 140. In other words, the gate electrode 105 can be said to be arranged between the substrate 100 and the oxide semiconductor layer 140. The gate insulating layer 110 can be said to be arranged between the gate electrode 105 and the oxide semiconductor layer 140. The gate insulating layer 120 can be said to be arranged between the gate insulating layer 110 and the oxide semiconductor layer 140. Although details will be described later, in the present embodiment, the gate insulating layer 110 contains silicon nitride. The gate insulating layer 120 includes silicon oxide. The gate electrode 105 may be referred to as a “second gate electrode.” The gate insulating layer 110 may be referred to as a “fourth insulating layer.” The gate insulating layer 120 may be referred to as a “fifth insulating layer.”

The gate insulating layers 110 and 120 have a stacked structure. The insulating layer 130 is arranged on the gate insulating layer 120. In other words, the insulating layer 130 is arranged between the gate insulating layer 120 and the oxide semiconductor layer 140. The insulating layer 130 includes a metal oxide. The insulating layer 130 may be referred to as a “sixth insulating layer.” The metal oxide included in the insulating layer 130 may be referred to as a “second metal oxide”.

The oxide semiconductor layer 140 is arranged on the insulating layer 130. The insulating layer 130 and the oxide semiconductor layer 140 have a common planar shape. That is, an end of the insulating layer 130 substantially aligns with an end of the oxide semiconductor layer 140.

In this case, the term “common planar shape” means that each of the plurality of layers has substantially the same pattern in a plan view. For example, in the case where etching is performed on a plurality of different layers, a tapered shape may be formed at the pattern ends of each of the plurality of layers. In this case, since the pattern of the upper layer is smaller than the pattern of the lower layer, these patterns are not perfectly identical. However, even in such a case, the pattern of the upper layer and the pattern of the lower layer are said to have the common planar shape.

The gate insulating layer 510 is arranged on the oxide semiconductor layer 140 and the gate insulating layer 120 exposed from the oxide semiconductor layer 140. The gate insulating layer 510 is formed from the top surface of the oxide semiconductor layer 140 to the top surface of the gate insulating layer 120 over the pattern end of the oxide semiconductor layer 140. The gate insulating layers 520 and 530 and the gate electrode 540 are sequentially arranged on the gate insulating layer 510.

In other words, the gate electrode 540 is arranged on the oxide semiconductor layer 140 and faces the oxide semiconductor layer 140. The gate insulating layer 510 is arranged between the oxide semiconductor layer 140 and the gate electrode 540. The gate insulating layer 510 covers the pattern end of the oxide semiconductor layer 140. Although details will be described later, in the present embodiment, the gate insulating layer 510 includes silicon oxide. The gate electrode 540 may be referred to as a “first gate electrode.” The gate insulating layer 510 may be referred to as a “first insulating layer.”

The gate insulating layers 520 and 530 and the gate electrode 540 have the common planar shape. That is, an end of the gate insulating layer 520, an end of the gate insulating layer 530, and an end of the gate electrode 540 are substantially aligned. In a direction D1 between the source electrode 201 and the drain electrode 203, the lengths of the gate insulating layers 520 and 530, and the gate electrode 540 are shorter than the length of the gate electrode 105.

In other words, the gate insulating layers 520 and 530 are arranged on the gate insulating layer 510 between the oxide semiconductor layer 140 and the gate electrode 540. The gate insulating layer 530 is arranged on the gate insulating layer 520. Although details will be described later, in the present embodiment, the gate insulating layer 520 contains a metal oxide. The gate insulating layer 530 contains silicon nitride. The gate insulating layer 520 may be referred to as a “second insulating layer.” The gate insulating layer 530 may be referred to as a “third insulating layer.” The metal oxide included in the gate insulating layer 520 may be referred to as a “first metal oxide”.

The insulating layers 150 and 160 are arranged on the gate electrode 540 and the gate insulating layer 510. The insulating layers 150 and 160 have a stacked structure. The insulating layer 160 is arranged on the insulating layer 150. The insulating layers 150 and 160 cover the gate electrode 540. In other words, the insulating layers 150 and 160 cover a pattern end of the gate electrode 540. The insulating layer 150 is an insulating layer containing silicon nitride. The insulating layer 160 is an insulating layer including silicon oxide. The insulating layer 150 may be referred to as a “seventh insulating layer.” The insulating layer 160 may be referred to as an “eighth insulating layer.”

Openings 161 and 163 are arranged in the insulating layers 150 and 160 and the gate insulating layer 510. The openings 161 and 163 reach the oxide semiconductor layer 140. The source electrode 201 is arranged on the insulating layer 160 and inside the opening 161. The drain electrode 203 is arranged on the insulating layer 160 and inside the opening 163. The source electrode 201 and the drain electrode 203 are connected to the oxide semiconductor layer 140 at the bottom of the openings 161 and 163, respectively. The source electrode 201 is in contact with the connection wiring 220 shown in FIG. 1.

For example, a thickness of the gate insulating layer 110 is 50 nm or more and 500 nm or less, 50 nm or more and 400 nm or less, 50 nm or more and 300 nm or less, 50 nm or more and 150 nm or less, or 50 nm or more and 100 nm or less. For example, a thickness of the gate insulating layer 120 is 10 nm or more and 200 nm or less, or 10 nm or more and 100 nm or less. For example, a total thickness of the gate insulating layers 110 and 120 is 100 nm or more and 700 nm or less, 100 nm or more and 500 nm or less, 100 nm or more and 400 nm or less, 100 nm or more and 250 nm or less, 100 nm or more and 200 nm or less, or 100 nm or more and 150 nm or less.

For example, a thickness of the insulating layer 130 and the gate insulating layer 520 is 1 nm or more and 20 nm or less, or 1 nm or more and 10 nm or less. In the present embodiment, aluminum oxide is used as the insulating layer 130 and the gate insulating layer 520. Aluminum oxide has a high barrier property against gases such as oxygen or hydrogen. The barrier property means a function of suppressing the permeation of a gas such as oxygen or hydrogen through the aluminum oxide. That is, even if a gas such as oxygen or hydrogen is released from the layer arranged below the aluminum oxide film, the gas does not move to the layer arranged above the aluminum oxide film. Alternatively, even if a gas such as oxygen or hydrogen is released from the layer arranged above the aluminum oxide film, the gas does not move to the layer arranged below the aluminum oxide film.

A thickness of the oxide semiconductor layer 140 is 10 nm or more and 50 nm or less, 10 nm or more and 40 nm or less, or 10 nm or more and 30 nm or less. Thicknesses of the insulating layers 150 and 160 are 50 nm or more and 300 nm or less, 60 nm or more and 200 nm or less, or 70 nm or more and 150 nm or less.

For example, a thickness of the gate insulating layer 510 is 50 nm or more and 200 nm or less, or 50 nm or more and 100 nm or less. Since the thickness of the gate insulating layer 510 is within the above-described range, the reliability of the semiconductor device 20 against visible light and radiation is improved, as will be described later.

For example, a thickness of the gate insulating layer 530 is 50 nm or more and 300 nm or less, 50 nm or more and 200 nm or less, or 50 nm or more and 100 nm or less. Since the thickness of the gate insulating layer 530 is within the above-described range, a withstand voltage against an applied voltage of the gate insulating layer required for the semiconductor device 20 can be ensured.

### [3. Material of Each Member of Radiation Detector 10]

### [3.1 Substrate]

A rigid substrate having translucency, such as a glass substrate, a quartz substrate, or a sapphire substrate, is used as the substrate 100. In the case where the substrate 100 needs to have flexibility, a substrate containing a resin such as a polyimide substrate, an acrylic substrate, a siloxane substrate, or a fluorine resin substrate is used as the substrate 100. In the case where a substrate containing a resin is used as the substrate 100, impurities may be introduced into the resin in order to improve the heat resistance of the substrate 100. A substrate that does not have translucency, such as a silicon substrate, a silicon carbide substrate, a semiconductor substrate such as a compound semiconductor substrate, or a conductive substrate such as a stainless steel substrate, may be used as the substrate 100.

[3-2. Conductive Layers such as Electrodes and Wirings]

General metal materials are used as the gate electrodes 105 and 540, the source/drain electrode 200, the light-shielding layer 210, the connection wiring 220, the lower electrode 310, and the wiring 360. For example, aluminum (Al), titanium (Ti), chromium (Cr), cobalt (Co), nickel (Ni), molybdenum (Mo), hafnium (Hf), tantalum (Ta), tungsten (W), bismuth (Bi), silver (Ag), copper (Cu), and an alloy or compound thereof are used as these members. The materials described above may be used in a single layer or in a stacked layer as these electrodes and wirings. In the case where the light-shielding layer 210 does not need to be electrically conductive, a black resin may be used as the light-shielding layer 210.

A transparent conductive layer is used as the upper electrode 320 and the wiring 350. A mixture of indium oxide and tin oxide (ITO) and a mixture of indium oxide and zinc oxide (IZO) may be used as the transparent conductive layer. A material other than the above may be used as the transparent conductive layer.

### [3-3. Insulating Layer]

A general insulating material is used as the gate insulating layers 110, 120, 510 and 530, and the insulating layers 150, 160 and 330. For example, an inorganic insulating layer containing oxygen such as silicon oxide (SiOₓ), silicon oxynitride (SiOₓN_{y}), aluminum oxide (AlOₓ), or aluminum oxynitride (AlOₓN_{y}) is used as the gate insulating layers 120 and 510, and the insulating layer 160. An inorganic insulating layer containing nitrogen such as silicon nitride (SiNₓ), silicon nitride oxide (SiNₓO_{y}), aluminum nitride (AlNₓ), or aluminum nitride oxide (AlNₓO_{y}) is used as the gate insulating layers 110 and 530, and the insulating layer 150. However, the inorganic insulating layer containing oxygen as described above may also be used as the gate insulating layer 110 and the insulating layer 150. The inorganic insulating layer containing nitrogen as described above may be used as the gate insulating layer 120 and the insulating layer 160.

An insulating layer having a function of releasing oxygen by a heat treatment is used as the gate insulating layer 510. That is, an oxide insulating layer containing excess oxygen is used as the gate insulating layer 510. For example, the temperature of the heat treatment in which the gate insulating layer 510 releases oxygen is 600° C. or lower, 500° C. or lower, 450° C. or lower, or 400° C. or lower. That is, for example, the gate insulating layer 510 releases oxygen at a heat treatment temperature performed in a manufacturing process of the semiconductor device 20 in the case where a glass substrate is used as the substrate 100.

An insulating layer with few defects is used as the gate insulating layer 120. For example, in the case where a composition ratio of oxygen in the gate insulating layer 120 is compared with a composition ratio of oxygen in an insulating layer having the same composition as that of the gate insulating layer 120 (hereinafter referred to as “other insulating layer”), the composition ratio of oxygen in the gate insulating layer 120 is closer to a stoichiometric ratio with respect to the insulating layer than the composition ratio of oxygen in the other insulating layer. Specifically, in the case where silicon oxide (SiOₓ) is used for each of the gate insulating layer 120 and the gate insulating layer 510, the composition ratio of oxygen in the silicon oxide used as the gate insulating layer 120 is closer to a stoichiometric ratio of silicon oxide than the composition ratio of oxygen in the silicon oxide used as the gate insulating layer 510. For example, a layer in which no defects are observed when evaluated by electron-spin resonance (ESR) may be used as the gate insulating layer 120.

SiOₓN_{y} and AlOₓN_{y} are a silicon compound and aluminum compound containing a smaller proportion (x>y) of nitrogen (N) than oxygen (O). SiNₓO_{y} and AlNₓO_{y} are a silicon compound and aluminum compound containing a smaller proportion (x>y) of oxygen than nitrogen.

An organic insulating layer is used as the insulating layers 230 and 340. For example, polyimide resin, acrylic resin, epoxy resin, silicone resin, fluorine resin, and siloxane resin are used as the organic insulating layer.

A metal oxide containing aluminum as a main component is used as the insulating layers 130 and 520. For example, an inorganic insulating layer such as aluminum oxide (AlOₓ) or aluminum oxynitride (AlOₓN_{y}) is used as the insulating layers 130 and 520. The “insulating layers 130 and 520 containing aluminum as a main component” means that the proportion of aluminum contained in the insulating layers 130 and 520 is 1% or more of the entire metal oxide layer. The proportion of aluminum contained in the insulating layers 130 and 520 may be 5% or more and 70% or less, 10% or more and 60% or less, or 30% or more and 50% or less of the entire metal oxide layer. The ratio described above may be a mass ratio or a weight ratio.

### [3-4. Oxide Semiconductor Layer]

An oxide semiconductor layer containing two or more metals including indium (In) is used as the oxide semiconductor layer 140. For example, an oxide semiconductor containing indium (In), gallium (Ga), zinc (Zn), and oxygen (O) may be used as the oxide semiconductor layer 140. For example, an oxide semiconductor having a composition ratio of In:Ga:Zn:O=1:1:1:4 may be used as the oxide semiconductor layer 140. However, the oxide semiconductor containing In, Ga, Zn, and O used in the present embodiment is not limited to the components described above. An oxide semiconductor having a composition different from that described above may be used as the oxide semiconductor. For example, an oxide semiconductor layer having a higher ratio of In than those described above may be used in order to improve mobility. On the other hand, an oxide semiconductor layer having a higher ratio of Ga than those described above may be used in order to enlarge a bandgap and reduce the effects of light irradiation.

For example, an oxide semiconductor layer having a ratio of indium element to the total amount of metal elements may be 50% or more in an atomic ratio may be used as the oxide semiconductor layer 140 having a higher composition of In than those described above. Gallium (Ga), zinc (Zn), aluminum (Al), hafnium (Hf), yttrium (Y), zirconia (Zr), and lanthanoids may be used as the oxide semiconductor layer 140 in addition to indium. An element other than the elements described above may be used as the oxide semiconductor layer 140.

The oxide semiconductor layer 140 may be the oxide semiconductor containing In, Ga, Zn, and O to which other elements may be added, and a metal element such as Al or Sn may be added. In addition to the oxide semiconductor described above, an oxide semiconductor containing In and Zn (IZO), an oxide semiconductor containing In, Sn, and Zn (ITZO), an oxide semiconductor containing In, Sn, Ga, and Zn (ITGZO), and an oxide semiconductor containing In and Ga (IGO), or the like may be used as the oxide semiconductor layer 140.

In the case where the proportion of the indium element is high, the oxide semiconductor layer 140 is easily crystallized. As described above, in the oxide semiconductor layer 140, the oxide semiconductor layer 140 having the polycrystalline structure can be easily obtained by using a material in which the proportion of the indium element to the entire metal element is 50% or more. The oxide semiconductor layer 140 preferably contains gallium as a metal element other than indium. Gallium belongs to the same Group 13 element as indium. Therefore, crystallinity of the oxide semiconductor layer 140 is not inhibited by gallium, and the oxide semiconductor layer 140 has the polycrystalline structure.

In the case where the proportion of the indium element to the entire metal element of the oxide semiconductor layer 140 is 50% or more, the oxide semiconductor layer 140 has translucency and has a polycrystalline structure including a plurality of crystal grains. Although details will be described later, the oxide semiconductor layer 140 having the polycrystalline structure can be formed by using a Poly-OS (Poly-crystalline Oxide Semiconductor) technique. Hereinafter, although a configuration of the oxide semiconductor layer 140 will be described, an oxide semiconductor having a polycrystalline structure may be referred to as the Poly-OS.

For example, a size of the crystal grain contained in the Poly-OS is 0.1 μm or more, 0.3 μm or more, or 0.5 μm or more. For example, the size of the crystal grain can be obtained by a cross-sectional SEM observation, a cross-sectional TEM observation, or an electron back scattered diffraction (EBSD) method.

As described above, since the size of the crystal grain contained in the Poly-OS is 0.1 μm or more, in the oxide semiconductor layer 140 having a thickness of 10 nm or more and 30 nm or less, there is a region containing only one crystal grain along a thickness direction.

The oxide semiconductor layer 140 can be formed using a sputtering method. A composition of the oxide semiconductor layer 140 formed by the sputtering method depends on a composition of a sputtering target. Even in the case where the oxide semiconductor layer 140 has the polycrystalline structure, the composition of the sputtering target and the composition of the oxide semiconductor layer 140 substantially coincide with each other. In this case, the composition of the metal element of the oxide semiconductor layer 140 can be specified based on the composition of the metal element of the sputtering target.

In the case where the oxide semiconductor layer 140 has the polycrystalline structure, the composition of the oxide semiconductor layer may be specified using an X-ray Diffraction (XRD) method. Specifically, the composition of the metal element of the oxide semiconductor layer can be specified based on the crystal structure and a lattice constant of the oxide semiconductor layer obtained by the XRD method. In addition, the composition of the metal element of the oxide semiconductor layer 140 can be determined using fluorescent X-ray analysis, or Electron Probe Micro Analyzer (EPMA) analysis, or the like. However, the oxygen element contained in the oxide semiconductor layer 140 varies depending on the process conditions of sputtering and the like, so that it may not be specified by these methods.

### [3-5. Poly-OS Technique]

The Poly-OS contained in the oxide semiconductor layer is formed using sputtering and a heat treatment. In this case, a method for forming the oxide semiconductor layer will be described.

First, the oxide semiconductor layer is deposited by sputtering. The deposited oxide semiconductor layer has an amorphous structure. In this case, the amorphous structure means a structure in which a long-range ordered structure does not exist and a periodic crystal lattice arrangement is not observed. For example, when the oxide semiconductor layer having an amorphous structure is observed using the XRD method, a certain peak based on the crystalline structure cannot be obtained in the diffractive pattern. The oxide semiconductor layer having an amorphous structure may have a short-range ordered structure in a micro region. However, such an oxide semiconductor layer does not exhibit characteristics of the Poly-OS and can therefore be classified as an oxide semiconductor layer having an amorphous structure.

In the Poly-OS technique, the oxide semiconductor layer is deposited at a low temperature. For example, a temperature of a substrate on which the oxide semiconductor layer is deposited is 150° C. or lower, preferably 100° C. or lower, and more preferably 50° C. or lower. When the temperature of the substrate is high during the deposition of the oxide semiconductor layer, microcrystals are likely to be generated in the oxide semiconductor to be deposited. The oxygen partial pressure in a chamber during deposition is 1% or more and 10% or less, preferably 1% or more and 5% or less, and more preferably 2% or more and 4% or less. When the oxygen partial pressure is high, microcrystals are generated in the oxide semiconductor layer due to excess oxygen contained in the oxide semiconductor. On the other hand, under the condition where the oxygen partial pressure is less than 1%, the composition of oxygen in the oxide semiconductor layer becomes uneven, and an oxide semiconductor layer containing a large amount of microcrystals or an oxide semiconductor layer which does not crystallize even when subjected to a heat treatment is deposited.

Next, a heat treatment is performed on the oxide semiconductor layer deposited by sputtering. The heat treatment is performed in the atmosphere, but the atmosphere of the heat treatment is not limited to this. The temperature of the heat treatment is 300° C. or higher and 500° C. or lower, preferably 350° C. or higher and 450° C. or lower. The time of the heat treatment is 15 minutes or more and 120 minutes or less, preferably 30 minutes or more and 60 minutes or less. By performing the heat treatment, the oxide semiconductor layer having an amorphous structure is crystallized to form the oxide semiconductor layer containing the Poly-OS.

### [4. Electrical Characteristics of Semiconductor Device 20]

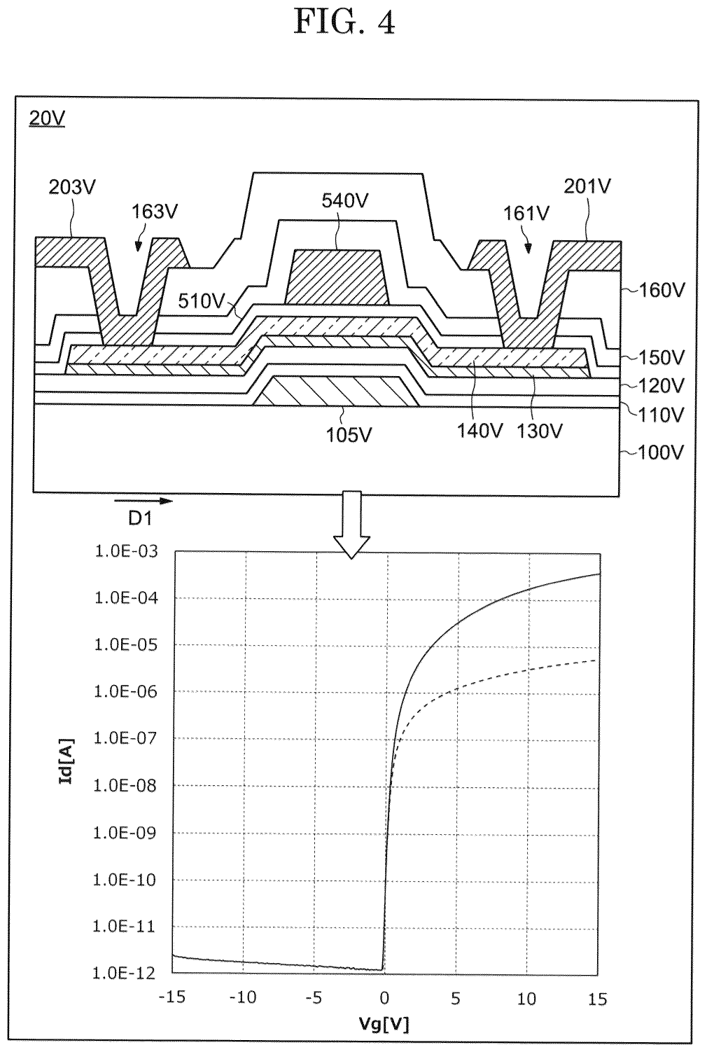

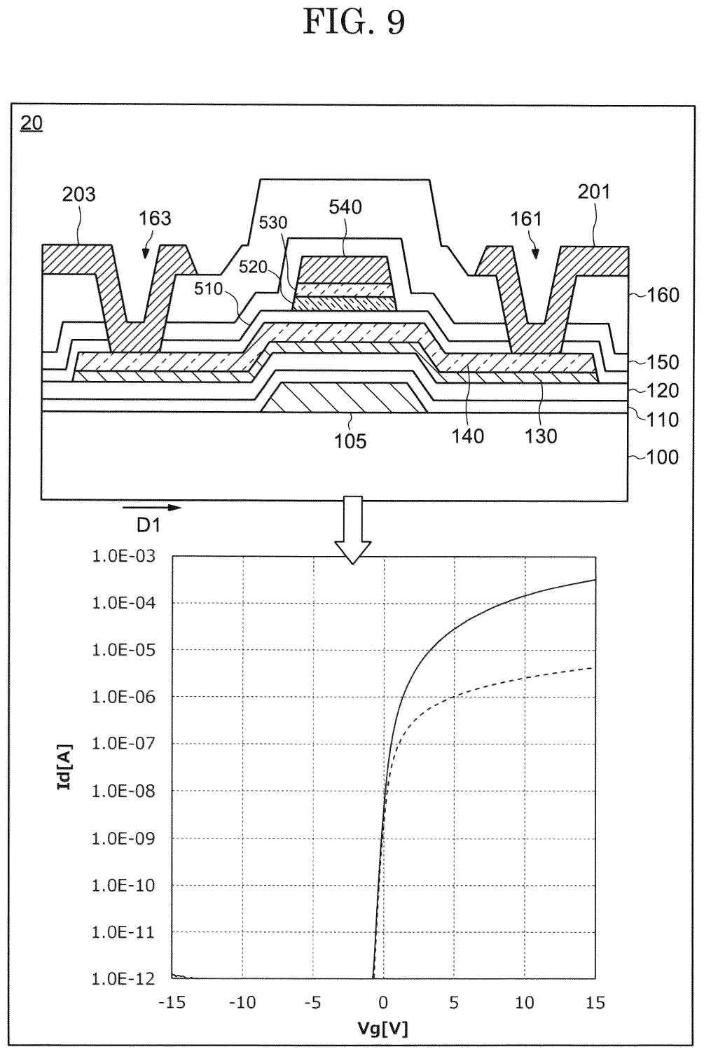

FIG. 4 to FIG. 8 are cross-sectional views of a semiconductor device according to a comparative example and their electrical characteristics. FIG. 9 is a cross-sectional view of a semiconductor device according to an embodiment of the present invention and its electrical characteristics. In FIG. 4 to FIG. 9, a structure of a semiconductor device in which the electric characteristics are evaluated is shown together with the electric characteristics. The effect obtained by the structure according to the present embodiment will be described with reference to a cross-sectional structure of the semiconductor device according to each of the comparative example and the present embodiment and the electrical characteristics thereof using FIG. 4 to FIG. 9.

The conditions for measuring the electrical characteristics shown in FIG. 4 to FIG. 9 are as follows. The vertical axis of the respective electrical characteristics represents a drain-current value (Id [A]), and the horizontal axis represents a gate-voltage value (Vg [V]).
Size of channel region CH: W/L=4.5 μm/3.0 μm
Source-drain voltage: 0.1 V (dotted line), 10 V (solid line)
Gate voltage: −15 V to +15 V
Measurement environment: room temperature, dark room

### [4-1. Conventional Semiconductor Device]

FIG. 4 shows a conventional semiconductor device and its electrical characteristics as a comparative example. A semiconductor device 20V shown in FIG. 4 is similar to the semiconductor device 20 shown in FIG. 3. However, the semiconductor device 20V does not have members corresponding to the gate insulating layers 520 and 530 of the semiconductor device 20, and a gate electrode 540V is in contact with a gate insulating layer 510V. The electrical characteristics of the semiconductor device 20V are good. However, in the semiconductor device 20V, for example, the threshold fluctuates greatly due to a radiation irradiation test using X-rays.

It is known that the threshold variation due to the radiation irradiation test occurs when holes generated in an oxide semiconductor layer 140V by the irradiation are trapped by hole traps in the oxide insulating layer adjacent to the oxide semiconductor layer 140V. Therefore, in order to improve the resistance of the semiconductor device 20V to the radiation irradiation test, a thickness of the gate insulating layer 510V needs to be reduced.

However, in a structure of the semiconductor device 20V, in the case where the thickness of the gate insulating layer 510V is small, not only the withstand voltage of the gate insulating layer 510V is low, but also it is difficult to adjust an impurity implantation process for reducing a resistance of the oxide semiconductor layer 140V in source and drain regions not overlapping the gate electrode 540V in a plan view. The above problem can be solved by thinning the gate insulating layer 510V and adding an insulating layer containing silicon nitride between the gate insulating layer 510V and the gate electrode 540V.

[4-2. Semiconductor Device with Silicon Nitride Layer to Gate Insulating Layer]

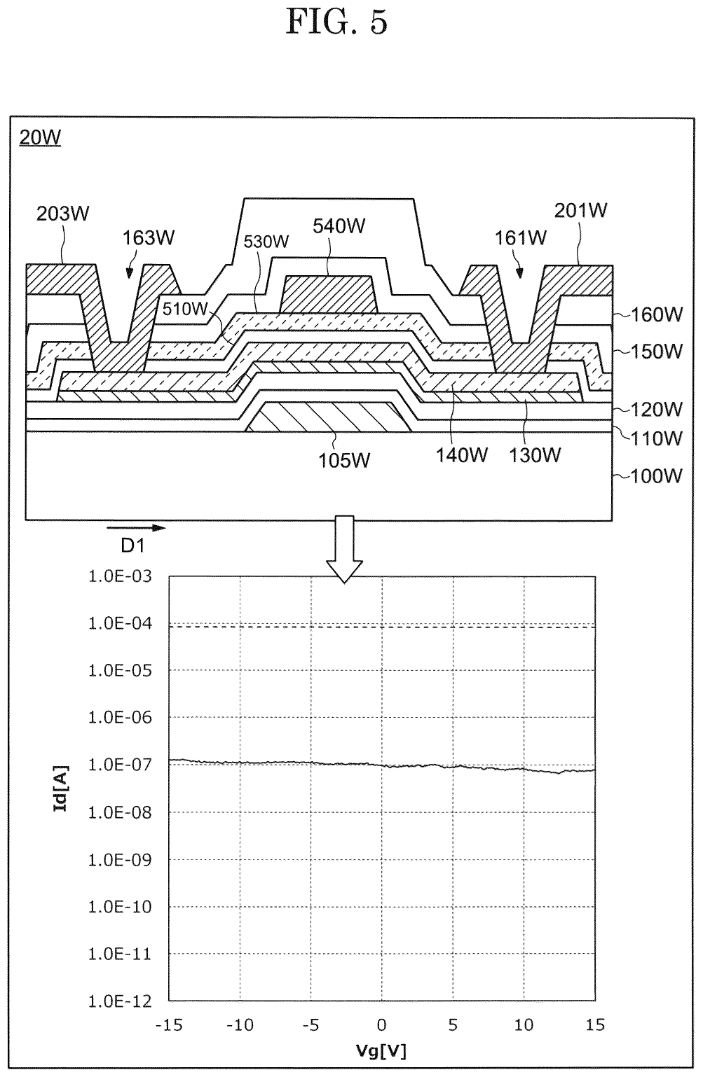

FIG. 5 shows a semiconductor device 20W and its electrical characteristics as a comparative example. In the semiconductor device 20W, unlike the conventional semiconductor device 20V, a gate insulating layer 530W containing silicon nitride is arranged between a gate insulating layer 510W and a gate electrode 540W. As shown in FIG. 5, in the semiconductor device 20W, the gate insulating layer 530W extends not only below the gate electrode 540W but also to the outside of a pattern of the oxide semiconductor layer 140W, similar to the gate insulating layer 510W. The electrical characteristics of the semiconductor device 20W are poor, and the semiconductor device 20W does not function as a switching element (it is not turned off).

Since silicon nitride contains a large amount of hydrogen, the hydrogen diffuses into the oxide semiconductor layer 140W during the deposition of the gate insulating layer 530W and by the heat treatment after the deposition of the gate insulating layer 530W. When hydrogen reaches the oxide semiconductor layer 140W, the oxide semiconductor layer 140W becomes N-type due to the reduction action of hydrogen. As a result, as shown in FIG. 5, the semiconductor device 20W does not have a switching function. In particular, in the semiconductor device 20W, since the gate insulating layer 530W is formed on the entire surface, a large amount of hydrogen diffuses into the oxide semiconductor layer 140W.

As described above, the reason why the semiconductor device 20W does not have the switching function is that the oxide semiconductor layer 140W has become N-type by diffusing hydrogen contained in the silicon nitride into the oxide semiconductor layer 140W. Therefore, the above-described problem can be suppressed by reducing the amount of hydrogen diffused into the oxide semiconductor layer 140W. Since it is sufficient that the gate insulating layer 530W is arranged between the gate insulating layer 510W and the gate electrode 540W, the amount of hydrogen can be reduced by removing the gate insulating layer 530W other than between the gate insulating layer 510W and the gate electrode 540W.

[4-3. Semiconductor Device in which Silicon Nitride Layer is Patterned to Match Gate Electrode]

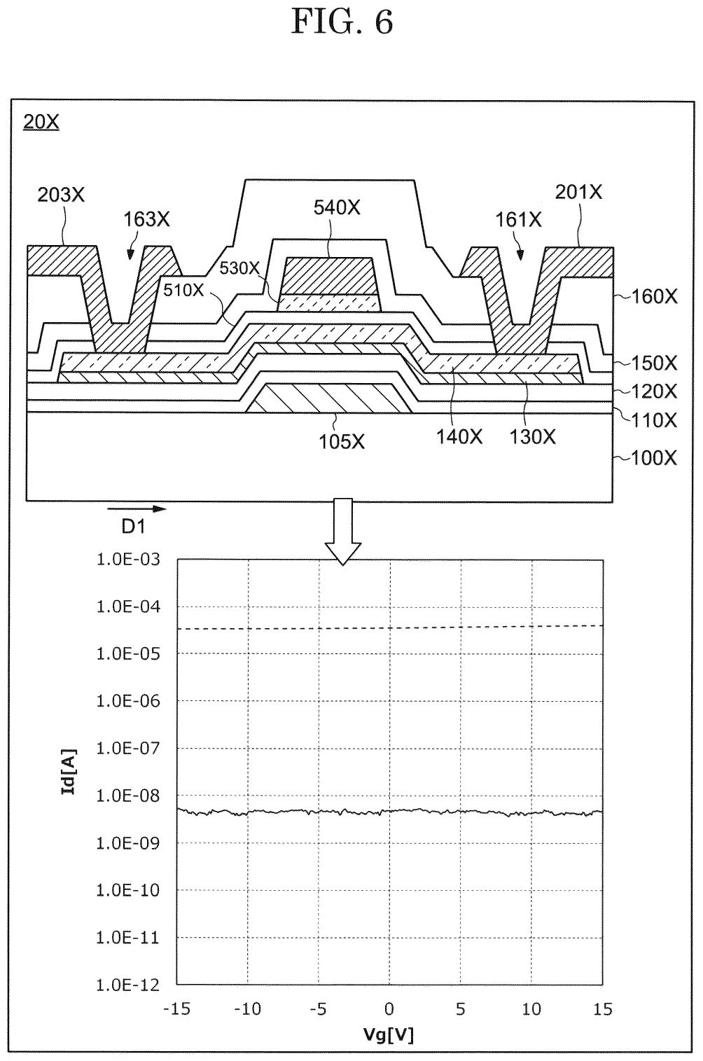

FIG. 6 shows a semiconductor device 20X and its electrical characteristics as a comparative example. In the semiconductor device 20X, unlike the semiconductor device 20W shown in FIG. 5, a gate insulating layer 530X in a region not overlapping a gate electrode 540X in a plan view is removed. As shown in FIG. 6, in the semiconductor device 20X, the gate insulating layer 530X is arranged only between a gate insulating layer 510X and the gate electrode 540X, and the gate insulating layer 530X is not arranged in a region not overlapping the gate electrode 540X in a plan view. The electrical characteristics of the semiconductor device 20X are poor, and the semiconductor device 20X does not function as a switching element (it is not turned off).

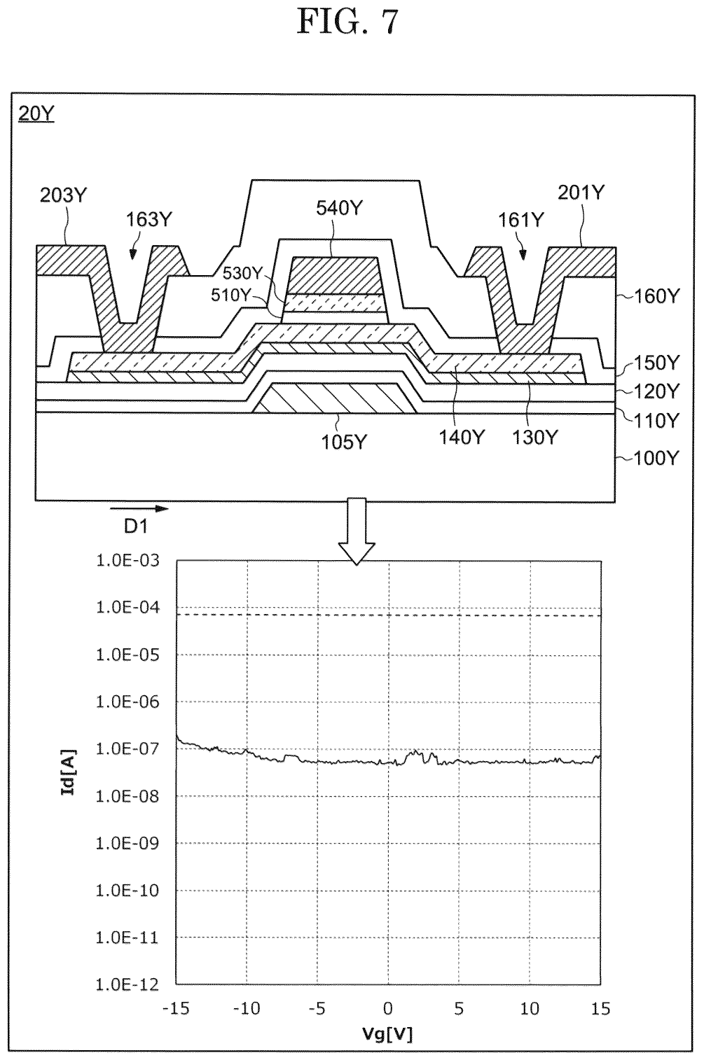

FIG. 7 shows a semiconductor device 20Y and its electrical characteristics as a comparative example. In the semiconductor device 20Y, unlike the semiconductor device 20W shown in FIG. 5, gate insulating layers 510Y and 530Y in a region not overlapping a gate electrode 540Y in a plan view are removed. As shown in FIG. 7, in the semiconductor device 20Y, both the gate insulating layers 510Y and 530Y are formed in the same pattern as the gate electrode 540Y. The electrical characteristics of the semiconductor device 20Y are poor, and the semiconductor device 20Y does not function as a switching element (it is not turned off).

As described above, in a region not overlapping the gate electrodes 540X and 540Y in a plan view, even when only the gate insulating layer 530X is removed, even when both the gate insulating layers 510Y and 530Y are removed, it was impossible to prevent the oxide semiconductor layers 140X and 140Y from becoming N-type. In this case, since the metal oxide containing aluminum as a main component can suppress the diffusion of hydrogen, for example, by arranging the metal oxide between the gate insulating layers 530X and 530Y and the gate insulating layers 510X and 510Y, it is possible to suppress the oxide semiconductor layers 140X and 140Y from becoming N-type.

[4-4. Semiconductor Device with Aluminum Oxide Layer between Silicon Nitride Layer and Silicon Oxide Layer]

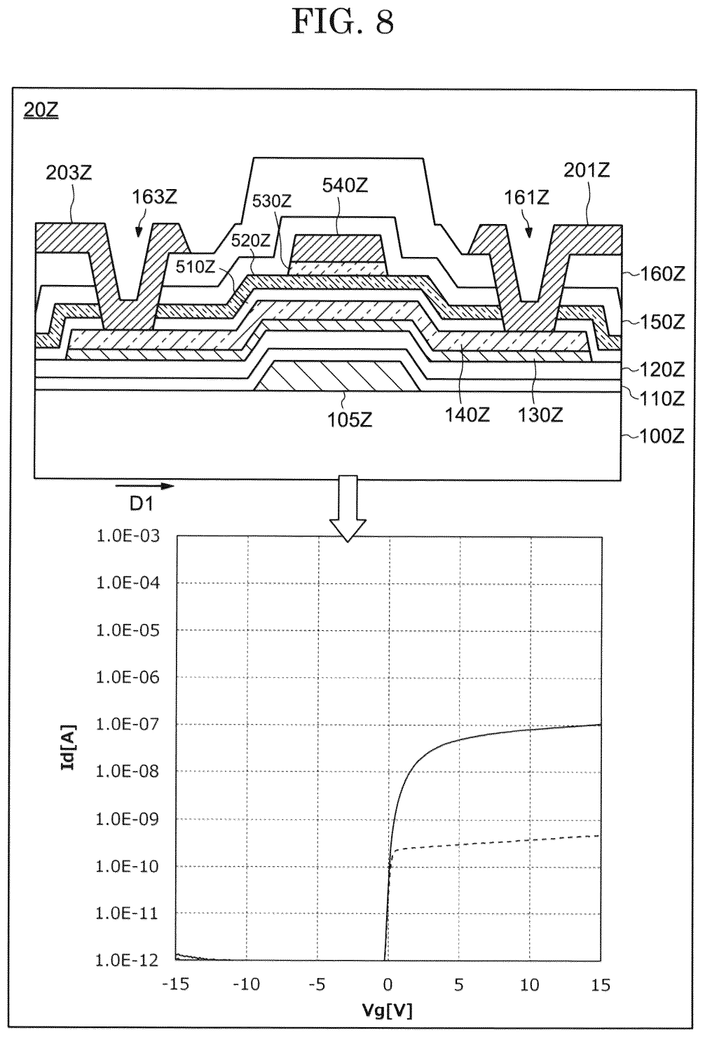

FIG. 8 shows a semiconductor device 20Z and its electrical characteristics as a comparative example. In the semiconductor device 20Z, unlike the semiconductor device 20X shown in FIG. 6, a gate insulating layer 520Z containing metal oxide containing aluminum as a main component is arranged between a gate insulating layer 510Z and a gate insulating layer 530Z. In the present embodiment, an example in which aluminum oxide is used as the metal oxide will be described. As shown in FIG. 8, in the semiconductor device 20Z, the gate insulating layer 520Z extends not only below a gate electrode 540Z but also to the outside of a pattern of an oxide semiconductor layer 140Z, similar to the gate insulating layer 530Z. The electric characteristics of the semiconductor device 20Z are different from the electric characteristics of the semiconductor devices 20W to 20Y and have a function as a switching element (switchable between on-state and off-state). On the other hand, the semiconductor device 20Z has a problem of low on-state.

Although details will be described later, in the semiconductor device 20Z, a process of implanting impurities into the oxide semiconductor layer 140 is performed to reduce the resistance of the oxide semiconductor layer 140Z in the source and drain regions. Oxygen vacancies are formed in the oxide semiconductor layer 140Z by the implantation of impurities. It has been found that a low resistance of the oxide semiconductor layer 140Z can be realized by diffusing hydrogen from an insulating layer 150Z to the oxygen vacancies.

On the other hand, in a configuration of the semiconductor device 20Z shown in FIG. 8, the gate insulating layer 520Z (aluminum oxide) is arranged on the entire surface below the insulating layer 150Z. Since aluminum oxide suppresses the diffusion of hydrogen, the diffusion of hydrogen contained in the insulating layer 150Z into the oxide semiconductor layer 140Z is suppressed. As a result, even if oxygen vacancies are formed in the oxide semiconductor layer 140Z by the implantation of impurities, hydrogen does not diffuse into the oxygen vacancies, and the resistance of the oxide semiconductor layer 140Z in the source and drain regions is not reduced. As a result, as shown in FIG. 8, the on-state current is low in a part of the semiconductor device 20Z.

In view of the above, as shown in FIG. 9, in the semiconductor device 20 according to the present embodiment, the gate insulating layer 520 in the source and drain regions is removed so that hydrogen contained in the insulating layer 150 can diffuse into the oxide semiconductor layer 140 and reduce the resistance of the oxide semiconductor layer 140 in the source and drain regions. As a result, the decrease in the on-state current confirmed in FIG. 8 is eliminated, and the semiconductor device 20 has a satisfactory function as a switching element.

### [5. Radiation Resistance of Semiconductor Device 20]

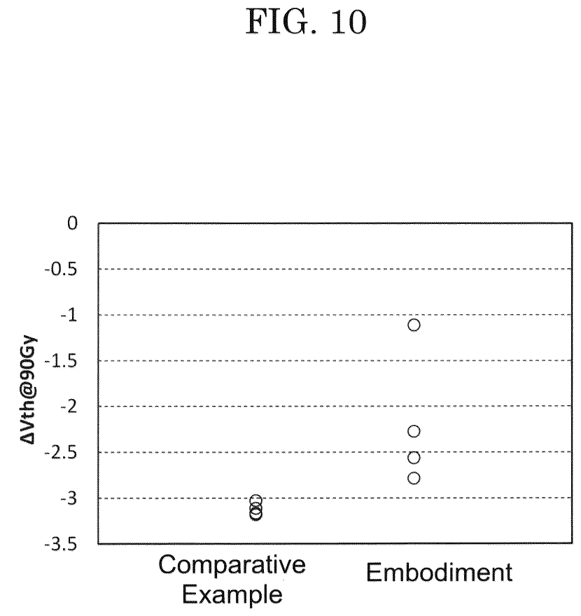

FIG. 10 is a diagram showing a reliability test against radiation of a semiconductor device according to an embodiment of the present invention. The reliability test shown in FIG. 10 is the result of an X-ray irradiation test. The graph shown in FIG. 10 shows the amount of change in a threshold voltage Vth obtained from the electrical characteristics before and after the X-ray irradiation.

The conditions of the X-ray irradiation test are as follows.
Size of channel region: W/L=4.5 μm/3.0 μm
Number of transistors evaluated: 4
X-ray irradiator: MBR-1520R-3 (manufactured by Hitachi Power Solutions)
X-ray irradiation conditions: 90Gy (20 mA contiguous irradiation)
X-ray irradiation conditions: Filter Al=1 mm

The vertical axis (ΔVth@90Gy) in FIG. 10 represents the amount of change in the threshold voltage Vth before and after the X-ray irradiation. In FIG. 10, the semiconductor device according to the example is the semiconductor device 20 shown in FIG. 3. The thicknesses of the gate insulating layer 510 (silicon oxide) and the gate insulating layer 530 (silicon nitride) of the semiconductor device 20 are both 50 nm. The semiconductor device according to the comparative example is the semiconductor device 20V shown in FIG. 4. The thickness of the gate insulating layer 510V of the semiconductor device 20V is 75 nm.

As shown in FIG. 10, the threshold variation before and after the X-ray irradiation test of the semiconductor device 20 according to the embodiment is smaller than the threshold variation before and after the X-ray irradiation test of the semiconductor device 20V according to the comparative example. This is because the amount of hole traps included in the gate insulating layer 510 in the example is smaller than the amount of hole traps included in the gate insulating layer 510V in the comparative example due to the difference in the thickness between the gate insulating layer 510 and the gate insulating layer 510V.

### [6. Method for Manufacturing Semiconductor Device 20]

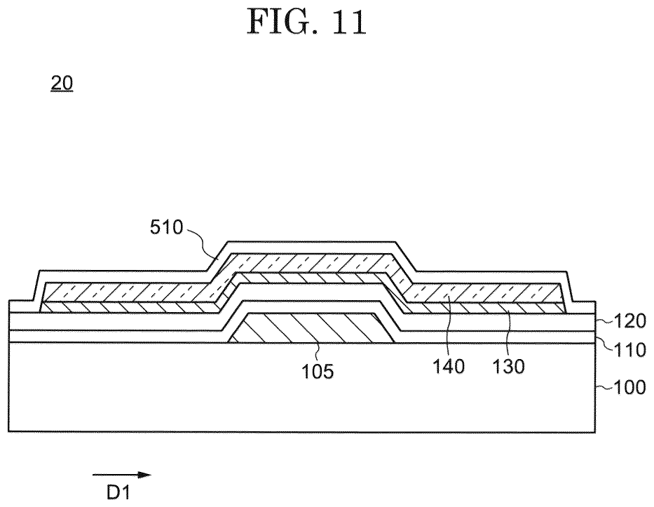

A method for manufacturing a semiconductor device according to an embodiment of the present invention will be described with reference to FIG. 11 to FIG. 18. FIG. 11 to FIG. 18 are cross-sectional views showing a method for manufacturing a semiconductor device according to an embodiment of the present invention. In the following description of the manufacturing method, a method for manufacturing the semiconductor device 20 in which silicon nitride is used as the gate insulating layers 110 and 530, silicon oxide is used as the gate insulating layers 120 and 510, and aluminum oxide is used as the insulating layer 130 and the gate insulating layer 520 will be described.

As shown in FIG. 11, the gate electrode 105 is formed as a bottom gate on the substrate 100, and the gate insulating layers 110 and 120 are formed on the gate electrode 105. Silicon nitride is formed as the gate insulating layer 110. Silicon oxide is formed as the gate insulating layer 120. The gate insulating layers 110 and 120 are formed by a CVD (Chemical Vapor Deposition) method.

The use of silicon nitride as the gate insulating layer 110 allows the gate insulating layer 110 to block impurities that diffuse, for example, from the substrate 100 toward the oxide semiconductor layer 140.

The insulating layer 130 and the oxide semiconductor layer 140 are formed on the gate insulating layer 120. Aluminum oxide is used as the insulating layer 130. The oxide semiconductor layer 140 is formed in contact with the insulating layer 130. The insulating layer 130 and the oxide semiconductor layer 140 are deposited by sputtering or atomic layer deposition (ALD).

A resist mask is formed on the oxide semiconductor layer 140, and the insulating layer 130 and the oxide semiconductor layer 140 are etched using the resist mask. Wet etching or dry etching may be used as the etching of the oxide semiconductor layer 140. The wet etching may be performed using an acidic etchant. For example, an etching solution containing phosphoric acid as a main component or hydrofluoric acid may be used as the etchant.

After that, the insulating layer 130 is etched with the patterned oxide semiconductor layer 140 as a mask. Wet etching or dry etching may be used as the etching of the insulating layer 130. For example, dilute hydrofluoric acid (DHF) is used as the wet etching. As described above, the photolithography process can be omitted by etching the insulating layer 130 using the oxide semiconductor layer 140 as a mask.

The gate insulating layer 510 is deposited on the patterned insulating layer 130 and the oxide semiconductor layer 140 as described above. Silicon oxide is deposited as the gate insulating layer 510. The gate insulating layer 510 is formed by the CVD method. For example, the gate insulating layer 510 may be deposited at a deposition temperature of 350° C. or higher in order to form an insulating layer with few defects as described above as the gate insulating layer 510.

Although the configuration in which the insulating layer 130 is arranged below the oxide semiconductor layer 140 is exemplified in the present embodiment, the insulating layer 130 may be omitted.

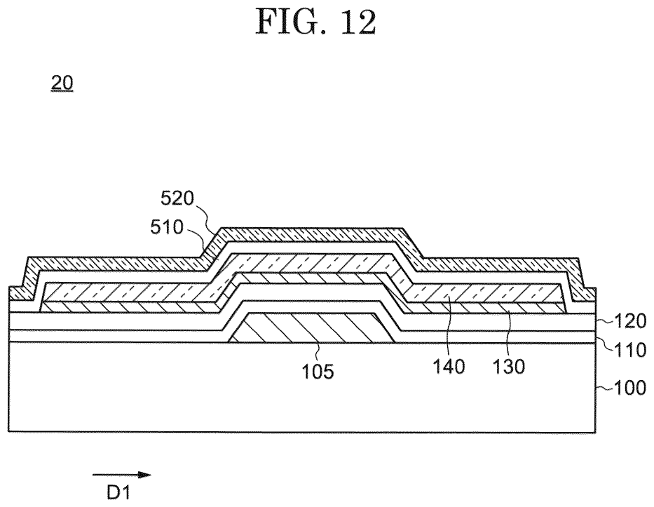

As shown in FIG. 12, the gate insulating layer 520 is deposited on the gate insulating layer 510. The gate insulating layer 520 is formed by the sputtering method. By depositing the gate insulating layer 520, oxygen and a process gas used in the sputtering method are implanted into the gate insulating layer 510. Argon is often used as the process gas in the sputtering method. Therefore, the gate insulating layer 510 may contain argon.

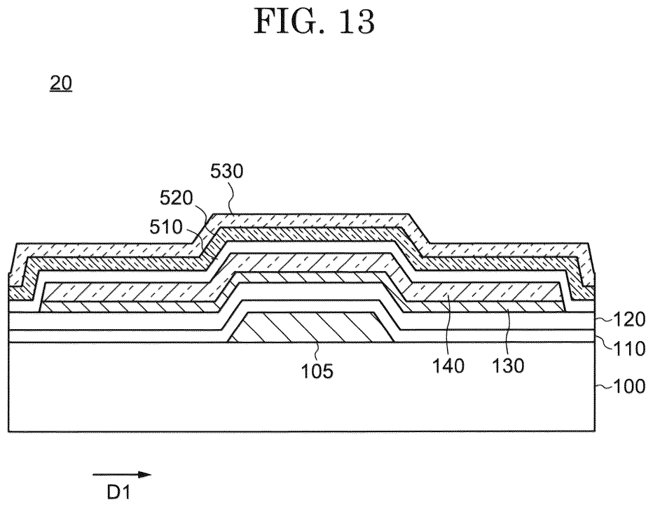

As shown in FIG. 13, the gate insulating layer 530 is deposited on the gate insulating layer 520. Silicon nitride is deposited as the gate insulating layer 530. The gate insulating layer 530 is formed by the CVD method.

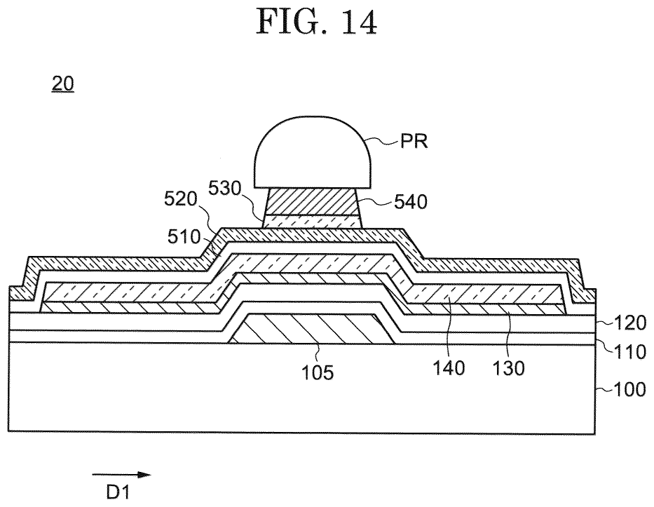

As shown in FIG. 14, a conductive layer is deposited on the gate insulating layer 530, a photoresist PR is formed on the conductive layer, and the conductive layer and the gate insulating layer 530 are etched using the photoresist PR as a mask. The gate electrode 540 is formed by this etching.

For example, in the case where an alloy of molybdenum and tungsten (MoW) is used as the gate electrode 540, dry etching in which SF₆ and O₂ are used as the process gas is used as the etching of MoW. The dry etching has a high etching rate with respect to silicon nitride, but a low etching rate with respect to aluminum oxide. Therefore, as shown in FIG. 14, the gate electrode 540 and the gate insulating layer 530 are etched together using the photoresist PR as a mask, and the gate insulating layer 520 functions as a stopper for the etching.

A stacked layer of titanium (lower layer) and MoW (upper layer) may be used as the gate electrode 540 in addition to MoW as a single layer. A material other than MoW may be used in a single layer or in a stacked layer as the gate electrode 540. The conductive layer constituting the gate electrode 540 is formed by the sputtering method.

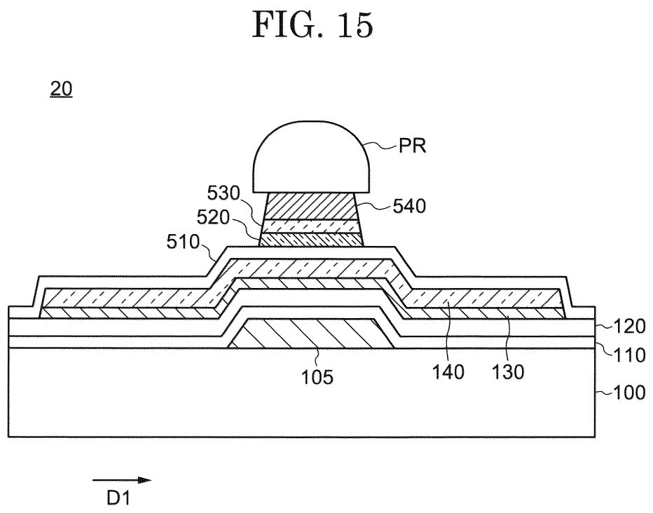

As shown in FIG. 15, the gate insulating layer 520 is etched using the photoresist PR, the gate electrode 540, and the gate insulating layer 530 as masks. This etching results in a configuration in which the pattern ends of each of the gate electrode 540, the gate insulating layer 530, and the gate insulating layer 520 are aligned. That is, the etching results in a configuration in which the gate insulating layer 520 has the same planar shape as the gate electrode 540 and the gate insulating layer 530.

In the case where MoW is used as the gate electrode 540, the etching of the gate insulating layer 520 may be performed with the photoresist PR formed or may be performed with the photoresist PR removed.

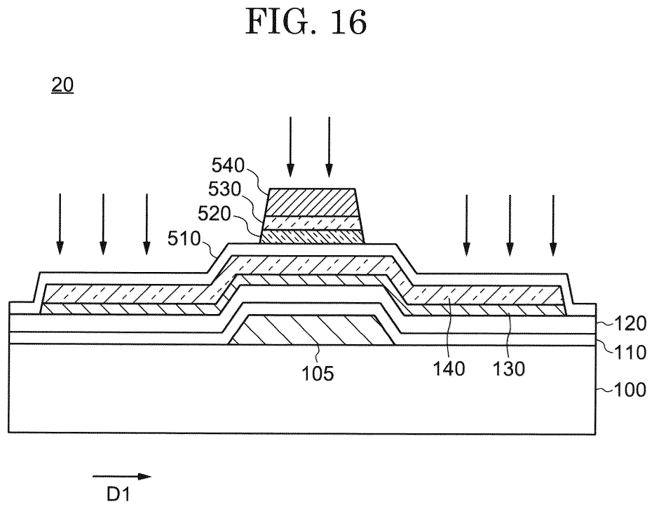

As shown in FIG. 16, after the photoresist PR is removed, ion implantation is performed on the oxide semiconductor layer 140. As shown in FIG. 16, since the gate insulating layer 510 is formed on the oxide semiconductor layer 140, ions which have passed through the gate insulating layer 510 are implanted into the oxide semiconductor layer 140. However, since the implanted ions are blocked by the gate electrode 540, no ions are implanted into the oxide semiconductor layer 140 in a region overlapping the gate electrode 540 in a plan view.

For example, boron (B) is implanted as an impurity element into the oxide semiconductor layer 140 by ion implantation. However, other impurity elements such as phosphorus (P) may be implanted into the oxide semiconductor layer 140 instead of boron.

Impurity elements are implanted into the oxide semiconductor layer 140 in the source and drain regions by the ion implantation described above. In the oxide semiconductor layer 140 in the source and drain regions, oxygen vacancies are formed by the implantation of impurity elements. When hydrogen is trapped in the oxygen vacancies, the resistance of the oxide semiconductor layer 140 in the source and drain regions is reduced.

In the oxide semiconductor layer 140 containing the Poly-OS, the oxide semiconductor layer 140 may have crystallinity even in the source and drain regions into which the impurity element is implanted. This is also one of the characteristics of the Poly-OS. In this case, the crystal structure of each of the source and drain regions is the same as the crystal structure of the channel region overlapping the gate electrode 540 in a plan view.

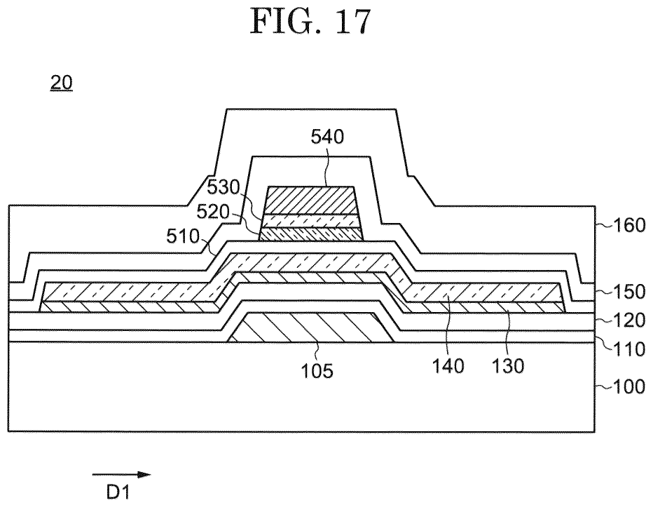

As shown in FIG. 17, the insulating layers 150 and 160 are deposited as an interlayer film on the gate insulating layer 510 and the gate electrode 540. The insulating layers 150 and 160 are deposited by the CVD method. Silicon nitride is formed as the insulating layer 150 and silicon oxide is formed as the insulating layer 160. The materials used as the insulating layers 150 and 160 are not limited to the above.

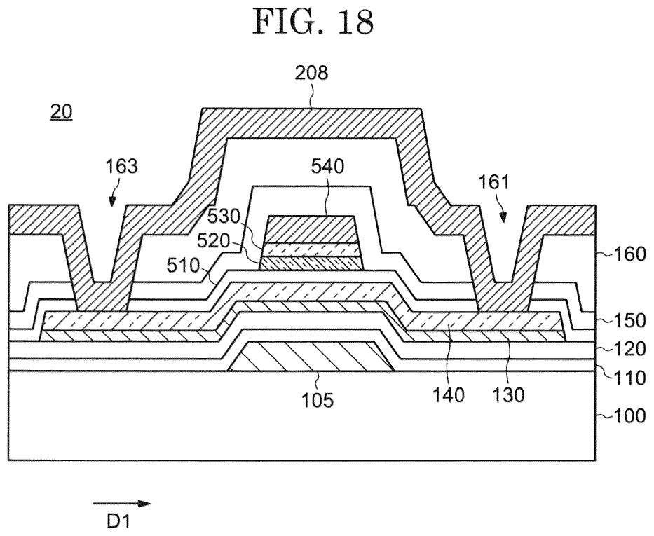

As shown in FIG. 18, the openings 161 and 163 are formed in the insulating layers 150 and 160 and the gate insulating layer 510. The openings 161 and 163 are formed to expose the oxide semiconductor layer 140, respectively. A conductive layer 208 is deposited on the insulating layer 160 and inside the openings 161 and 163, and the conductive layer 208 is patterned to form the source electrode 201 and the drain electrode 203 as shown in FIG. 3.

Each of the embodiments described above as the embodiment of the present invention can be appropriately combined as long as they are not mutually contradictory. Further, based on the semiconductor device and the radiation detector of each embodiment, additions, deletions, or design changes of the components, or those additions, deletions, or condition changes of the steps made by a person skilled in the art as appropriate are also included in a scope of the present invention as long as it comprises the gist of the present invention.

It is to be understood that the present invention provides other operational effects that are different from operational effects provided by aspects of the embodiments described above, and those that are obvious from descriptions of the present specification or those that can be easily predicted by a person skilled in the art.

What is claimed is:

1. A semiconductor device comprising:
a semiconductor layer arranged above an insulating surface;
a first gate electrode arranged above the semiconductor layer and facing the semiconductor layer;
a first insulating layer arranged between the semiconductor layer and the first gate electrode and containing a silicon oxide covering a pattern end of the semiconductor layer;
a second insulating layer arranged above the first insulating layer between the semiconductor layer and the first gate electrode, the second insulating layer having a common planar shape with the first gate electrode and containing a first metal oxide; and
a third insulating layer arranged above the second insulating layer between the semiconductor layer and the first gate electrode, the third insulating layer having a common planar shape with the first gate electrode and containing a silicon nitride.

2. The semiconductor device according to claim 1, further comprising:
a second gate electrode arranged between the insulating surface and the semiconductor layer; and
a fourth insulating layer arranged between the second gate electrode and the semiconductor layer.

3. The semiconductor device according to claim 1, wherein the semiconductor layer includes an oxide semiconductor.

4. The semiconductor device according to claim 1, wherein the semiconductor layer includes an oxide semiconductor having a poly-crystalline structure.

5. The semiconductor device according to claim 1, further comprising:
a second gate electrode arranged between the insulating surface and the semiconductor layer;
a fourth insulating layer arranged between the second gate electrode and the semiconductor layer and containing a silicon nitride;
a fifth insulating layer arranged between the fourth insulating layer and the semiconductor layer and containing a silicon oxide;
a sixth insulating layer arranged between the fifth insulating layer and the semiconductor layer and containing a second metal oxide; and
the semiconductor layer includes an oxide semiconductor having a poly-crystalline structure.

6. The semiconductor device according to claim 5, wherein the first metal oxide and the second metal oxide contain aluminum as a main component.

7. The semiconductor device according to claim 6, wherein a thickness of the second insulating layer is 1 nm or more and 20 nm or less.

8. The semiconductor device according to claim 5, wherein
a thickness of the first insulating layer is 50 nm or more and 200 nm or less, and
a thickness of the third insulating layer is 50 nm or more and 300 nm or less.

9. The semiconductor device according to claim 5, further comprising:
a seventh insulating layer arranged above the first gate electrode, covering a pattern end of the first gate electrode, and containing a silicon nitride; and
an eighth insulating layer arranged above the seventh insulating layer and containing a silicon oxide.

10. A radiation detector comprising:
the semiconductor device according to claim 1;
a photoelectric conversion layer connected to the semiconductor device; and
a wavelength conversion layer facing the photoelectric conversion layer and configured to emit visible light based on an irradiated radiation.
